(19) United States
(12) Patent Application Publication
(10) Pub. No.: US 2013/0008776 A1
(43) Pub. Date: Jan. 10, 2013

(54) METHOD OF FORMING CARBON FILM, AND METHOD OF MANUFACTURING MAGNETIC RECORDING MEDIUM

(75) Inventors: Satoru Nakajima, Ichihara-shi (JP); Ichiro Ota, Chiba-shi (JP)

(73) Assignee: SHOWA DENKO K.K., Minato-ku, Tokyo (JP)

(21) Appl. No.: 13/634,098

(22) PCT Filed: Mar. 3, 2011
(86) PCT No.: PCT/JP2011/054889

§ 371 Date: Sep. 11, 2012

(30) Foreign Application Priority Data
Mar. 12, 2010 (JP) 2010-055611

(51) Int. Cl. C23C 14/46

(52) U.S. Cl. 204/192.11

(57) ABSTRACT

There is provided a method of forming a carbon film which enables formation of a dense carbon film exhibiting high wettability with respect to a lubricant and also having high hardness, the method of forming a carbon film including: introducing a raw material gas (G) containing carbon and hydrogen into a deposition chamber having a reduced pressure; ionizing the gas (G) by electric discharge between a filamentous cathode electrode that is heated through energization and an anode electrode provided in the periphery of the cathode electrode; and accelerating the ionized gas by a bias voltage that is applied to a substrate (D) to irradiate the surface of the substrate (D) with the accelerated gas, thereby forming a carbon film on the surface of the substrate (D), wherein a pulsed negative voltage is employed as the bias voltage to be applied to the surface of the substrate (D).

### BACKGROUND OF THE INVENTION

1. Field of the Invention

The present invention relates to a method of forming a carbon film, and a method of manufacturing a magnetic recording medium.

Priority is claimed on Japanese Patent Application No. 2010-055611, filed Mar. 12, 2010, the contents of which are incorporated herein by reference.

2. Description of Related Art

In recent years, in the field of magnetic recording media used in, for example, hard disk drives (HDDs), recording density has improved significantly, and the recording density has continued to increase dramatically at a rate of about 1.5 times a year. Many different technologies are responsible for these huge improvements in recording density, but one of the key technologies has been technology for controlling the sliding characteristics between the magnetic head and the magnetic recording medium.

For example, since the CSS (contact start-stop) system also known as the Winchester system, in which the basic operations from the start to the stop of a magnetic head with respect to the magnetic recording medium involve contact sliding, head lifting and contact sliding, has become the main system employed within hard disk drives, contact and sliding of the magnetic head on the magnetic recording medium has become unavoidable.

For this reason, problems relating to tribology between the magnetic head and the magnetic recording medium are currently an unavoidable technical issue. There has been a continuous attempt to improve the performance of the protective film laminated on the magnetic film of the magnetic recording medium, and the abrasion resistance and sliding resistance of the surface of the magnetic recording medium are the key factors in improving the reliability of the magnetic recording medium.

Various materials have been proposed as protective films for magnetic recording media, but from the overall viewpoints of film formability and durability and the like, carbon films are mainly employed. In addition, the properties of these carbon films such as the hardness, density, and dynamic friction coefficient are extremely important since they are vividly reflected in the CSS characteristics or corrosion resistance characteristics of the magnetic recording medium.

On the other hand, in order to improve the recording density of the magnetic recording medium, it is preferable to reduce the flying height of the magnetic head and to increase the number of rotations of the recording medium. Therefore, in order to cope with accidental contact of the magnetic head or the like, the protective film formed on the surface of the magnetic recording medium requires higher levels of sliding durability and flatness. In addition, in order to reduce the spacing loss between the magnetic recording medium and the magnetic head so as to improve the recording density, it is necessary to reduce the thickness of the protective film as much as possible, for example, to a film thickness of 30 Å or less, and there is a strong demand for a protective film which is not only smooth, but also thin, dense and strong.

In addition, the carbon film used as the protective film of the magnetic recording medium described above is formed by, for example, a sputtering method, a CVD method, or an ion beam deposition method. Among these methods, when the carbon film is formed by the sputtering method with a film thickness of for example, 100 Å or less, the durability of the carbon film may be unsatisfactory. On the other hand, when the carbon film formed by the CVD method has low surface smoothness and a small film thickness, the coverage over the surface of the magnetic recording medium is lowered, which may cause corrosion of the magnetic recording medium. In contrast, the ion beam deposition method is capable of forming a dense carbon film with high hardness and high smoothness, as compared to the sputtering method or CVD method described above.

As a method of forming a carbon film using the ion beam deposition method, for example, a method has been proposed, in which a deposition material gas enters a plasma state by electric discharge between a heated filamentous cathode and an anode in a deposition chamber in a vacuum atmosphere, and the resultant is then accelerated to collide with the surface of a substrate having a negative potential, thereby stably forming a carbon film with a high degree of hardness (refer to Patent Document 1).

In addition, in the above configuration, the mere provision of protective film is not sufficient for improving the durability of the magnetic recording medium. For this reason, the durability of the protective film is improved by applying a lubricant onto the surface of the protective film to form a lubricant layer with a thickness of about 0.5 to 3 nm. In other words, by providing a lubricant layer, it is possible to prevent the direct contact between the magnetic head (magnetic head slider) and the protective film, and also to significantly reduce the frictional force of the magnetic head (magnetic head slider) sliding on the magnetic recording medium.

Perfluoropolyether-based lubricants, aliphatic hydrocarbon-based lubricants or the like have been proposed as the lubricants. For example, a magnetic recording medium coated with a lubricant composed of perfluoroalkylpolyether having a structure of HOCH₂—CF₂O—(C₂F₄O)ₚ—(CF₂O)_{q}—CH₂OH (p and q represent an integer) has been disclosed in Patent Document 2. In addition, a magnetic recording medium coated with a lubricant composed of perfluoroalkylpolyether (tetraol) having a structure of HOCH₂CH(OH)—CH₂OCH₂CF₂O—(C₂F₄O)ₚ—(CF₂O)_{q}—CF₂CH₂OCH₂—CH(OH)CH₂OH (p and q represent an integer) has been disclosed in Patent Document 3. Furthermore, a lubricant for magnetic recording media application which includes a perfluorooxyalkylene unit selected from —CF₂O— or —CF₂CF₂O— as well as a phosphazene compound has been disclosed in Patent Document 4.

However, as the degree of hardness increases, the physical properties of carbon films become closer to those of diamonds to exhibit water repellency. In such cases, the contact angle at the carbon film surface with respect to the lubricant increases (the wettability decreases), making it impossible to provide a lubricant layer on the surface of the carbon film. For this reason, an increase in the wettability of the carbon film surface with respect to the lubricant has been described in Patent Document 5 by nitriding a 10 to 30% portion (in terms of the film thickness) of the carbon film from the surface thereof to alter the film quality to a carbon/hydrogen/nitrogen-based film.

Patent Document 1 Japanese Unexamined Patent Application, First Publication No. 2000-226659

Patent Document 2 Japanese Unexamined Patent Application, First Publication No. Sho 62-66417

Patent Document 3 Japanese Unexamined Patent Application, First Publication No. Hei 9-282642

Patent Document 4 Japanese Unexamined Patent Application, First Publication No. 2002-275484

Patent Document 5 Japanese Unexamined Patent Application, First Publication No. 2001-126233

### SUMMARY OF THE INVENTION

In order to further improve the recording density of the magnetic recording medium, it is necessary to reduce the thickness of the carbon film described above to a greater degree than ever before. Here, in order to reduce the thickness of the carbon film, it is necessary to increase the hardness of the carbon film. However, as a result, the wettability of the carbon film surface decreases with respect to the lubricant.

Here, although it is possible to employ a method to nitride the surface of the carbon film as described in Patent Document 5 so as to increase the wettability with respect to the lubricant, the hardness of the nitrided carbon film reduces, which makes it difficult to reduce the thickness of the carbon film.

The present invention has been proposed in view of such conventional circumstances, with an object of providing a method of forming a carbon film which enables formation of a dense carbon film exhibiting high wettability with respect to a lubricant and also having high hardness.

In addition, the present invention also has an object of providing a method of manufacturing a magnetic recording medium which is capable of obtaining a magnetic recording medium exhibiting excellent abrasion resistance and corrosion resistance with high recording density by employing a carbon film formed using the above method as a protective layer of the magnetic recording medium.

As a result of intensive and extensive studies in order to solve the above problems, the inventors of the present invention discovered the following facts. That is, carbon ions having a high excitation power can be formed, which is capable of forming a carbon film with high hardness, by introducing a raw material gas containing carbon and hydrogen into a deposition chamber under reduced pressure and then ionizing this raw material gas by electric discharge between a filamentous cathode electrode heated through energization and an anode electrode provided in the vicinity thereof. In addition, it was discovered that the hydrogen ionized by the electric discharge is also incorporated into the carbon film when these carbon ions are accelerated and irradiated onto the surface of the substrate, and these incorporated hydrogen ions lower the wettability of the carbon film with respect to the lubricant and also lower the hardness of the carbon film.

Further, it was found that a dense carbon film exhibiting high wettability with respect to a lubricant and also having high hardness can be formed by accelerating the ionized gas containing carbon and hydrogen due to the negative pulse bias applied to the substrate to irradiate onto the surface of the substrate, which has led to the completion of the present invention.

That is, the present invention provides the following aspects.

(1) A method of forming a carbon film including a step of introducing a raw material gas containing carbon and hydrogen into a deposition chamber having a reduced pressure; a step of ionizing the gas by electric discharge between a filamentous cathode electrode that is heated through energization and an anode electrode provided in the periphery of the cathode electrode; and accelerating the ionized gas by a bias voltage that is applied to a substrate to irradiate the surface of the substrate with the accelerated gas, thereby forming a carbon film on the surface of the substrate, wherein a pulsed negative voltage is employed as the bias voltage to be applied to the surface of the substrate.
(2) The method of forming a carbon film according to the above aspect (1) characterized in that a peak voltage of the aforementioned pulsed negative voltage is within the range of −30 to −500 V.
(3) The method of forming a carbon film according to the above aspect (1) or (2) characterized in that a frequency of the aforementioned pulsed negative voltage is within the range of 5 to 50 Hz.
(4) The method of forming a carbon film according to any one of the above aspect (1) to (3) characterized in that a pulse width of the aforementioned pulsed negative voltage is within the range of 15 milliseconds to 150 milliseconds.
(5) A method of manufacturing a magnetic recording medium characterized by including a step of forming a carbon film on a nonmagnetic substrate with at least a magnetic layer formed therein by using the method of forming a carbon film according to any one of the above aspect (1) to (4).

According to the present invention, a dense carbon film exhibiting high wettability with respect to a lubricant and having high hardness can be formed; and in the case of using this carbon film as a protective film for magnetic recording media or the like, the distance between the magnetic recording medium and the magnetic head can be narrowed because the film thickness of the carbon film can be further reduced. As a result, it is possible to increase the recording density of the magnetic recording medium and also to enhance the corrosion resistance of the magnetic recording medium.

### BRIEF DESCRIPTION OF THE DRAWINGS

FIG. 1 is a schematic configuration diagram schematically showing a carbon film forming apparatus to which the present invention has been applied.

FIG. 2A is a schematic diagram showing a magnetic field applied by a permanent magnet and the direction of the lines of magnetic force thereof.

FIG. 2B is a schematic diagram showing a magnetic field applied by a permanent magnet and the direction of the lines of magnetic force thereof.

FIG. 2C is a schematic diagram showing a magnetic field applied by a permanent magnet and the direction of the lines of magnetic force thereof.

FIG. 3 is a cross sectional view showing an example of a magnetic recording medium manufactured by applying the present invention.

FIG. 4 is a cross sectional view showing another example of a magnetic recording medium manufactured by applying the present invention.

FIG. 5 is a cross sectional view showing an example of a magnetic recording and reproducing apparatus.

FIG. 6 is a plan view showing a configuration of an in-line type film forming apparatus to which the present invention has been applied.

FIG. 7 is a side view showing a career of an in-line type film forming apparatus to which the present invention has been applied.

FIG. 8 is an enlarged side view showing the carrier shown in FIG. 7.

Hereinafter, an embodiment of the present invention will be described in detail with reference to the accompanying drawings.

It should be noted that those drawings used in the following description are showing characteristic portions enlarged in some cases for the sake of simplicity, in order to make them easy to understand, and thus the size and ratio of each component are not necessarily the same as the actual size and ratio thereof.

First, a method and apparatus for forming a carbon film to which the present invention has been applied will be described.

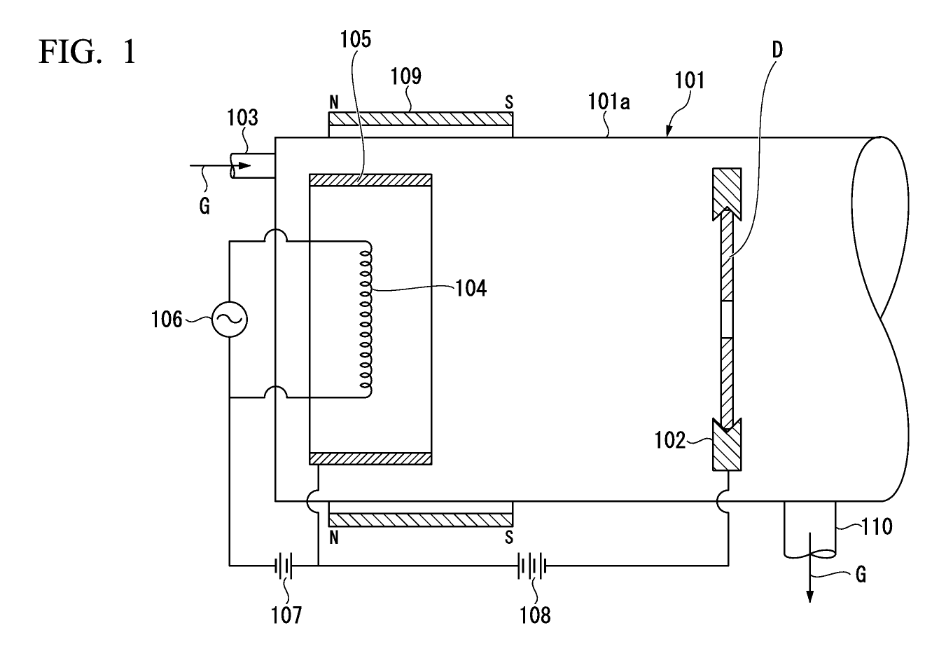

FIG. 1 is a schematic configuration diagram schematically showing a carbon film forming apparatus to which the present invention has been applied. As shown in FIG. 1, for example, this carbon film forming apparatus is a film forming apparatus using an ion beam deposition method, and includes a deposition chamber 101 whose internal pressure can be reduced, a holder 102 that holds a substrate D in the deposition chamber 101, an introduction pipe 103 that introduces a raw material gas G containing carbon and hydrogen into the deposition chamber 101, a filamentous cathode electrode 104 that is arranged in the deposition chamber 101, an anode electrode 105 that is arranged around the cathode electrode 104 in the deposition chamber 101, a first power supply 106 that heats the cathode electrode 104 through energization, a second power supply 107 that generates an electric discharge between the cathode electrode 104 and the anode electrode 105, a third pulsed power supply 108 that generates a negative pulsed potential difference between the cathode electrode 104 or the anode electrode 105 and the substrate D, and a permanent magnet 109 that applies a magnetic field between the cathode electrode 104 and the anode electrode 105 or the substrate D.

The deposition chamber 101 is configured of a chamber wall 101a in an airtight manner, and is also configured so that the internal pressure thereof can be reduced by evacuation through an exhaust pipe 110 connected to a vacuum pump (not shown). The first power supply 106 is an AC power supply that is connected to the cathode electrode 104, and supplies electrical power to the cathode electrode 104 during the formation of a carbon film. In addition, the first power supply 106 is not limited to the AC power supply, and a DC power supply may be used. The second power supply 107 is a DC power supply having a negative electrode side connected to the cathode electrode 104 and a positive electrode side connected to the anode electrode 105, and generates an electric discharge between the cathode electrode 104 and the anode electrode 105 during the formation of a carbon film. The third pulsed power supply 108 is a pulsed DC power supply having a positive electrode side connected to the anode electrode 105 and a negative electrode side connected to the holder 102 and generates a potential difference between the anode electrode 105 and the substrate D held by the holder 102 during the formation of a carbon film. In addition, the third pulsed power supply 108 may be configured so that the positive electrode side is connected to the cathode electrode 104.

Further, in the present invention, although depending on the size of the substrate D, when a carbon film is formed on a disk-like substrate having an outer diameter of 3.5 inches, it is preferable to set the voltage of the first power supply 106 within the range of 10 to 100 V and to set the DC or AC current thereof within the range of 5 to 50 A, and it is preferable to set the voltage of the second power supply 107 within the range of 50 to 300 V and to set the current thereof within the range of 10 to 5,000 mA.

In addition, it is preferable to set a peak voltage of the pulsed negative voltage of the third pulsed power supply 108 within the range of −30 to −500 V, and it is more preferable to set within the range of −200 to −450 V. When the peak voltage is higher than −30 V, the effects of the present invention are impaired, which is undesirable. On the other hand, when the peak voltage is lower than −500 V, an abnormal electrical discharge is likely to occur in an ion acceleration space, especially in the periphery of the holder 102 in the negative electrode side, which is undesirable.

In addition, it is preferable to set a frequency of the pulsed negative voltage of the third pulsed power supply within the range of 5 to 50 Hz, and it is more preferable to set within the range of 20 to 40 Hz. When the frequency is lower than 5 Hz, the effects of the present invention are impaired, which is undesirable. On the other hand, when the frequency is higher than 50 Hz, an abnormal electrical discharge is likely to occur in an ion acceleration space, especially in the periphery of the holder 102 in the negative electrode side, which is undesirable.

In addition, it is preferable to set a pulse width for the pulsed negative voltage of the third pulsed power supply within the range of 15 milliseconds to 150 milliseconds, and it is more preferable to set within the range of 30 milliseconds to 100 milliseconds. When the pulse width is smaller than 15 milliseconds, the effects of the present invention are impaired, which is undesirable. On the other hand, when the pulse width is greater than 150 milliseconds, the effects of the present invention are impaired, which is undesirable.

In addition, with respect to the third pulsed power supply, it is preferable to set the current within the range of 10 to 200 mA.

When a carbon film is formed on the surface of the substrate D by using the carbon film forming apparatus having a structure as described above, the raw material gas G containing carbon and hydrogen is introduced through the introduction pipe 103 into the deposition chamber 101 whose pressure is reduced through the exhaust pipe 110.

The raw material gas G is excited and decomposed into an ionized gas (carbon ions and hydrogen ions) by the thermal plasma of the filamentous cathode electrode 104 heated by the electric power supplied from the first power supply 106 and the plasma generated by the electric discharge between the anode electrode 105 and the cathode electrode 104 connected to the second power supply 107.

Then, the excited carbon ions in the plasma collide with the surface of the substrate D while being accelerated toward the substrate D with a negative potential by the third pulsed power supply 108 to form a carbon film.

In the present invention, the bias voltage supplied to the substrate D by the third pulsed power supply 108 is a pulsed negative potential. The reason why a dense carbon film exhibiting high wettability with respect to a lubricant and also having high hardness with high hardness can be formed by accelerating the carbon ions and hydrogen ions using such potential to collide with the surface of the surface D has not been fully elucidated yet. However, it is possible to consider that selected ions may be accelerated by using a pulsed voltage to thereby lower the hydrogen concentration in the carbon film, and also some carbon dangling bonds that have not been terminated with hydrogen are formed in the carbon film to thereby increase the wettability with respect to lubricants.

In the method of forming a carbon film to which the present invention has been applied, it is preferable to apply a magnetic field by the permanent magnet 109 arranged around the chamber wall 101a in a region in which the raw material gas G is ionized or a region in which the ionized gas (referred to as ion beams) is accelerated (hereafter, referred to as an excitation space).

In the present invention, when the carbon ions are accelerated and irradiated onto the surface of the substrate D, it is possible to increase the ion density of the carbon ions accelerated and irradiated toward the surface of the substrate D by applying a magnetic field from the outside. When the ion density in the excitation space is increased in this manner, an excitation force in the excitation space is increased. Accordingly, it is possible to accelerate and irradiate the carbon ions onto the surface of the substrate D with higher energy. As a result, it becomes possible to form a carbon film with high hardness and high density on the surface of the substrate D.

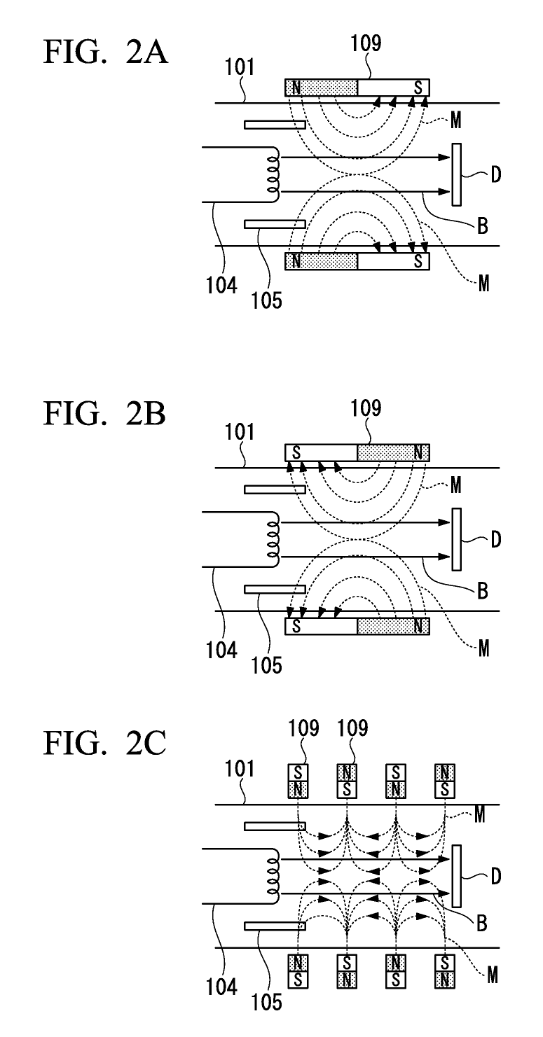

In the present invention, it is possible to apply a magnetic field to the excitation space in the deposition chamber 101 by using the permanent magnet 109 that is provided around the cathode electrode 104 and the anode electrode 105 described above. With respect to the magnetic field applied by the permanent magnet 109 and the direction of the lines of magnetic force thereof, for example, it is possible to employ the configuration as shown in FIGS. 2A to 2C.

That is, in the configuration shown in FIG. 2A (the same configuration as that shown in FIG. 1), the permanent magnet 109 is arranged around the chamber wall 101a of the deposition chamber 101 such that the S pole is close to the substrate D side and the N pole is close to the cathode electrode 104 side. In this configuration, the lines of magnetic force M generated by the permanent magnet 109 are substantially parallel to the direction in which ion beams B are accelerated in the vicinity of the center of the deposition chamber 101. By setting the direction of the lines of magnetic force M in the deposition chamber 101 in such a manner, it is possible to concentrate the carbon ions in the excitation space close to the center of the deposition chamber 101 by the magnetic moment thereof, and to efficiently increase the ion density in the excitation space.

In contrast, in the configuration shown in FIG. 2B, the permanent magnet 109 is arranged around the chamber wall 101a of the deposition chamber 101 such that the S pole is close to the cathode electrode 104 side and the N pole is close to the substrate D side. On the other hand, in the configuration shown in FIG. 2C, a plurality of permanent magnets 109 are arranged around the chamber wall 101a of the deposition chamber 101 such that the N pole and the S pole are alternately arranged on the inner circumferential side and the outer circumferential side. In all cases, the lines of magnetic force M generated by the permanent magnet 109 are substantially parallel to the direction in which the ion beams B are accelerated in the vicinity of the center of the deposition chamber 101. In this manner, it is possible to efficiently increase the ion density in the excitation space.

In addition, in the method of forming a carbon film to which the present invention has been applied, for example, a raw material gas containing hydrocarbons can be used as the raw material gas G containing carbon and hydrogen. It is preferable to use one or more types of lower hydrocarbons selected from lower saturated hydrocarbons, lower unsaturated hydrocarbons and lower cyclic hydrocarbons as the hydrocarbon. It should be noted that the term “lower” used herein refers to the case where the number of carbon atoms is in the range of 1 to 10.

Among the above-mentioned materials, for example, methane, ethane, propane, butane, octane or the like can be used as the lower saturated hydrocarbon. On the other hand, as the lower unsaturated hydrocarbon, isoprene, ethylene, propylene, butylene, butadiene, or the like can be used. In addition, as the lower cyclic hydrocarbon, it is possible to use benzene, toluene, xylene, styrene, naphthalene, cyclohexane, cyclohexadiene or the like.

In the present invention, it is preferable to use lower hydrocarbons, and the reason is as follows. When the number of carbon atoms in the hydrocarbon is greater than the above-mentioned range, it is difficult to supply the hydrocarbon as gas from the introduction pipe 103 and also to decompose the hydrocarbon during the electric discharge. As a result, the carbon film contains a large amount of polymer components with poor strength.

In the present invention, it is preferable to use a mixed gas prepared by incorporating an inert gas, a hydrogen gas or the like in the raw material gas G containing carbon and hydrogen in order to induce the generation of plasma in the deposition chamber 101. It is preferable that the mixing ratio of the hydrocarbon to the inert gas (i.e., hydrocarbon: inert gas ratio) or the like in the mixed gas be set within the range of 2:1 to 1:100 (volume ratio). As a result, it is possible to form a carbon film with high hardness and high durability.

It should be noted that in the carbon film forming apparatus shown above in FIG. 1, the carbon film is formed on only one surface of the substrate D. However, it is also possible to configure so that the carbon films may be formed on both surfaces of the substrate D. In this case, the same apparatus structure as that when the carbon film is formed on only one surface of the substrate D may be placed on both sides of the substrate D in the deposition chamber 101.

Next, a method of manufacturing a magnetic recording medium to which the present invention has been applied will be described.

In the present embodiment, a case will be described as an example in which an in-line type film forming apparatus that performs a deposition process while sequentially transporting a substrate, which is a deposition target, between a plurality of deposition chambers is used to manufacture a magnetic recording medium to be mounted on a hard disk device.

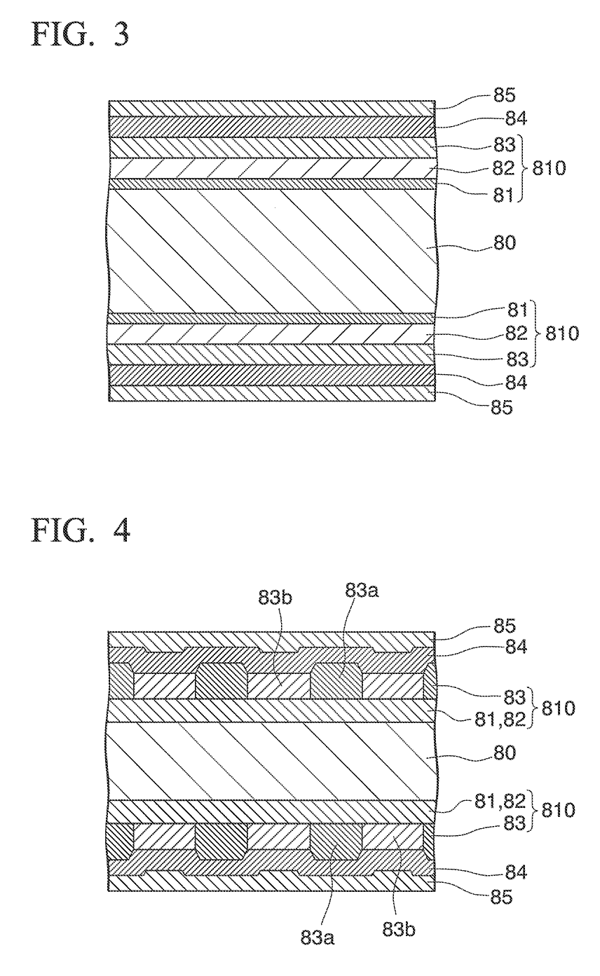

As shown in FIG. 3, for example, the magnetic recording medium manufactured according to the present invention has a structure in which soft magnetic layers 81, intermediate layers 82, recording magnetic layers 83, and protective layers 84 are sequentially laminated on both sides of a nonmagnetic substrate 80 and lubricant films 85 are further formed on the outermost surfaces. In addition, a magnetic layer 810 is constituted by the soft magnetic layer 81, the intermediate layer 82, and the recording magnetic layer 83.

Further, in the magnetic recording medium, as the protective layer 84, a dense carbon film exhibiting high wettability with respect to a lubricant and having high hardness is formed using the method of forming a carbon film according to the present invention described above. In this case, in the magnetic recording medium, it is possible to reduce the film thickness of the carbon film. More specifically, the film thickness of the carbon film can be reduced to about 2 nm or less.

Therefore, in the present invention, it becomes possible to narrow the distance between the magnetic recording medium as described above and the magnetic head. As a result, it is possible to increase the recording density of the magnetic recording medium and also to enhance the corrosion resistance of the magnetic recording medium.

Hereafter, layers other than the protective layer 84 in the above-mentioned magnetic recording medium will be described.

As the nonmagnetic substrate 80, any substrates can be used as long as it is a nonmagnetic substrate, such as Al alloy substrates made of, for example, an Al—Mg alloy or the like having Al as a main component; and substrates made of ordinary soda glass, aluminosilicate-based glass, crystallized glass, silicon, titanium, ceramics, and various types of resins.

Among these, it is preferable to use Al alloy substrates, glass substrates, such as crystallized glass, and silicon substrates. In addition, the average surface roughness (Ra) of these substrates is preferably equal to or less than 1 nm, more preferably equal to or less than 0.5 nm, and most preferably equal to or less than 0.1 nm.

The magnetic layer 810 may be an in-plane magnetic layer for an in-plane magnetic recording medium or a perpendicular magnetic layer for a perpendicular magnetic recording medium. However, it is preferable that the magnetic layer 810 be a perpendicular magnetic layer in order to achieve higher recording density. In addition, it is preferable that the magnetic layer 810 be formed from an alloy containing Co as the main component. For example, as the magnetic layer 810 for a perpendicular magnetic recording medium, a magnetic layer in which the soft magnetic layer 81 made of a soft magnetic alloy, such as a FeCo alloy (for example, FeCoB, FeCoSiB, FeCoZr, FeCoZrB, or FeCoZrBCu), a FeTa alloy (for example, FeTaN or FeTaC), or a Co alloy (for example, CoTaZr, CoZrNB, or CoB); the intermediate layer 82 made of Ru or the like; and the recording magnetic layer 83 made of a 60Co-15Cr-15Pt alloy or a 70Co-5Cr-15Pt-10SiO₂ alloy are laminated can be utilized. In addition, an orientation control film made of, for example, Pt, Pd, NiCr, or NiFeCr may be laminated between the soft magnetic layer 81 and the intermediate layer 82. On the other hand, a magnetic layer in which a nonmagnetic CrMo underlying layer and a ferromagnetic CoCrPtTa magnetic layer are laminated can be utilized as the magnetic layer 810 for an in-plane magnetic recording medium.

The thickness of the recording magnetic layer 83 is equal to or greater than 3 nm and equal to or less than 20 nm, preferably equal to or greater than 5 nm and equal to or less than 15 nm, and the recording magnetic layer 83 may be formed such that sufficient head input and output are obtained in accordance with the type of magnetic alloy used and the laminated structure thereof. The film thickness of the recording magnetic layer 83 needs to be equal to or greater than a certain value in order to achieve an output of at least a predetermined level during reproduction, although various parameters that indicate the recording and reproduction properties tend to deteriorate as the output increases, and therefore the film thickness must be set to an optimal value.

As a lubricant used for the lubricant film 85, a fluorine-based liquid lubricant, such as perfluoropolyether (PFPE), or a solid lubricant, such as fatty acid, may be used. In general, the lubricant layer 85 is formed with a thickness of 1 to 4 nm. As a method of applying the lubricant, a conventionally known method such as a dipping method or a spin coating method may be used.

In addition, as another example of a magnetic recording medium manufactured by applying the present invention, for example, as shown in FIG. 4, a so-called discrete-type magnetic recording medium may be used in which magnetic recording patterns 83a formed in the above-mentioned recording magnetic layer 83 are separated by nonmagnetic regions 83b.

In addition, with regard to the discrete-type magnetic recording medium, a so-called patterned medium in which the magnetic recording pattern 83a is regularly arranged for each bit or a medium in which the magnetic recording pattern 83a is arranged in the form of a track may be used. Alternatively, the magnetic recording pattern 83a may include, for example, a servo signal pattern.

Such a discrete-type magnetic recording medium is obtained by providing a mask layer on the surface of the recording magnetic layer 83 and exposing a portion which is not covered with the mask layer to a reactive plasma treatment, an ion irradiation treatment, or the like, thereby reforming a portion of the recording magnetic layer 83 from a magnetic body into a nonmagnetic body and forming the nonmagnetic regions 83b.

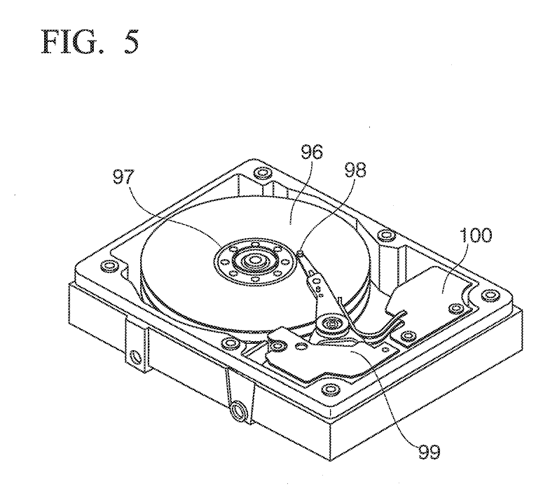

In addition, for example, a hard disk device as shown in FIG. 5 may be used as a magnetic recording and reproducing apparatus using the magnetic recording medium described above. The hard disk device includes a magnetic disk 96 which is the above magnetic recording medium, a medium driving unit 97 which rotationally drives the magnetic disk 96, a magnetic head 98 which records information on and reproduces information from the magnetic disk 96, a head driving unit 99, and a recording/reproduction signal processing system 100. Then, the magnetic reproducing signal processing system 100 processes input data, transmits recording signals to the magnetic head 98, processes the reproducing signal from the magnetic head 98 and outputs the processed data.

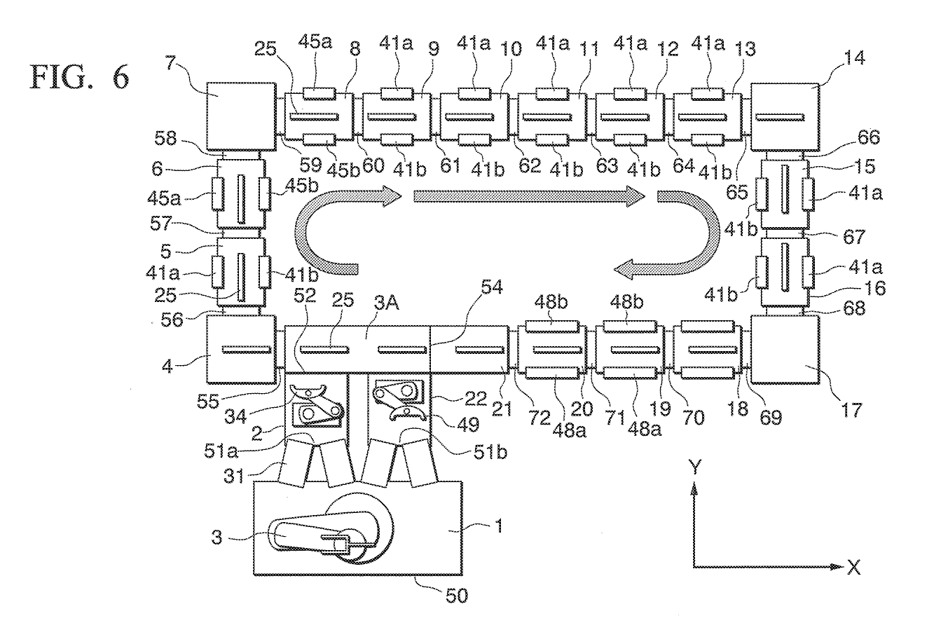

When manufacturing the above magnetic recording medium, for example, the in-line type film forming apparatus (an apparatus for manufacturing a magnetic recording medium) to which the present invention has been applied as shown in FIG. 6 is used to sequentially laminate the magnetic layers 810, each having at least the soft magnetic layer 81, the intermediate layer 82, and the recording magnetic layer 83, and the protective layers 84 on both sides of the nonmagnetic substrate 80, which is a deposition target, thereby stably manufacturing the above magnetic recording medium having a dense carbon film with high hardness as the protective layer 84.

More specifically, the in-line type film forming apparatus to which the present invention has been applied mainly includes: a robot base 1; a substrate transfer device 50 having a substrate transferring robot 3 that is mounted on the robot base 1; a substrate supplying robot chamber 2 that is provided adjacent to the robot base 1; a substrate supplying robot 34 that is arranged inside the substrate supplying robot chamber 2; a substrate attaching chamber 52 that is provided adjacent to the substrate supplying robot chamber 2; corner chambers 4, 7, 14, and 17 that rotate carriers 25; processing chambers 5, 6, 8 to 13, 15, 16, and 18 to 20 that are arranged between the respective corner chambers 4, 7, 14, and 17; a substrate detaching chamber 54 that is arranged adjacent to the processing chamber 20; an ashing chamber 3A that is arranged between the substrate attaching chamber 52 and the substrate detaching chamber 54; a substrate detaching robot chamber 22 that is arranged adjacent to the substrate detaching chamber 54; a substrate detaching robot 49 that is provided inside the substrate detaching robot chamber 22; and a plurality of carriers 25 that are transported between the respective chambers.

In addition, each of the chambers 2, 52, 4 to 20, 54, and 3A is connected to two adjacent wall portions, and gate valves 55 to 72 are provided in connecting portions of the chambers 2, 52, 4 to 20, 54, and 3A. When the gate valves 55 to 72 are closed, the inside of each chamber becomes an independent enclosed space.

In addition, vacuum pumps (not shown) are connected to each of the chambers 2, 52, 4 to 20, 54, and 3A. It is configured so that while sequentially transporting the carrier 25 into each chamber, whose internal pressure is reduced by the operation of these vacuum pumps, by a transport mechanism (not shown), the magnetic recording medium shown above in FIG. 3 is finally obtained by sequentially forming the aforementioned soft magnetic layer 81, the intermediate layer 82, the recording magnetic layer 83, and the protective layer 84 on both sides of the nonmagnetic substrate 80 that is mounted on the carrier 25 in each chamber. In addition, each of the corner chambers 4, 7, 14, and 17 is a chamber for changing the movement direction of the carrier 25, and inside thereof, there is provided a mechanism that rotates the carrier 25 and moves it to the next chamber.

The substrate transferring robot 3 supplies the nonmagnetic substrate 80 to the substrate attaching chamber 2 from a cassette having the nonmagnetic substrate 80 prior to deposition accommodated therein, and also takes out the nonmagnetic substrate 80 after the deposition (magnetic recording medium) which has been detached in the substrate detaching chamber 22. On a side wall of the substrate attaching chamber 2 and the substrate detaching chamber 22, an airlock chamber 31, and opening/closing units 51a and 51b are provided.

Inside the substrate attaching chamber 52, the nonmagnetic substrate 80 prior to deposition is mounted on the carrier 25 by using the substrate supplying robot 34. On the other hand, the carrier is transported to a carrier transfer chamber 21 after deposition, and inside the substrate detaching chamber 54, the nonmagnetic substrate 80 after the deposition (magnetic recording medium) which has been mounted on the carrier 25 is detached by using the substrate detaching robot 49. The ashing chamber 3A performs ashing of the carrier 25 transported from the substrate detaching chamber 54 and then transports the carrier 25 to the substrate attaching chamber 52.

Among the processing chambers 5, 6, 8 to 13, 15, 16, and 18 to 20, the processing chambers 5, 6, 8 to 13, 15, and 16 constitute a plurality of deposition chambers for forming the above-mentioned magnetic layer 810. These deposition chambers have mechanisms (41a, 41b, 45a and 45b) for forming the aforementioned soft magnetic layers 81, the intermediate layers 82, and the recording magnetic layers 83 on both sides of the nonmagnetic substrate 80.

On the other hand, the processing chambers 18 to 20 constitute a deposition chamber for forming the protective layer 84. Although there are three processing chambers in the apparatus employing the present configuration, the processing chambers used are appropriately selected in accordance with the thickness of the protective layer to be formed. These deposition chambers include the same apparatus configuration (48a, 48b) as that of the film forming apparatus using the ion beam deposition method as shown in FIG. 1, and form the aforementioned dense carbon film having high hardness as the protective layer 84 on the surface of the nonmagnetic substrate 80 having the above magnetic layer 810 formed thereon.

It should be noted that when the magnetic recording medium shown above in FIG. 4 is manufactured, the processing chambers may further include a patterning chamber that patterns a mask layer, a reforming chamber that performs a reactive plasma process or an ion beam process on a portion of the recording magnetic layer 83 that is not covered by the patterned mask layer so as to reform a portion of the recording magnetic layer 83 from a magnetic body into a nonmagnetic body, thereby forming the magnetic recording patterns 83b separated by the nonmagnetic regions 83b, and a removing chamber that removes the mask layer.

In addition, each of the processing chambers 5, 6, 8 to 13, 15, 16, and 18 to 20 is provided with a processing gas supply pipe, and a valve, whose opening or closing is controlled by a control mechanism (not shown), is provided in the supply pipe. By opening and closing these valves and the gate valves for pumps, the supply of gas from the processing gas supply pipe, the pressure inside the chambers, and the discharge of gas are controlled.

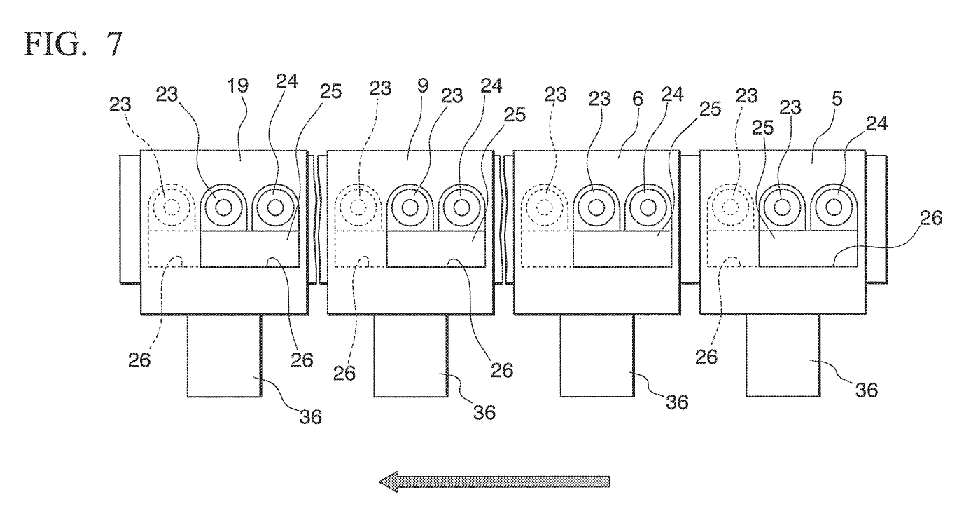

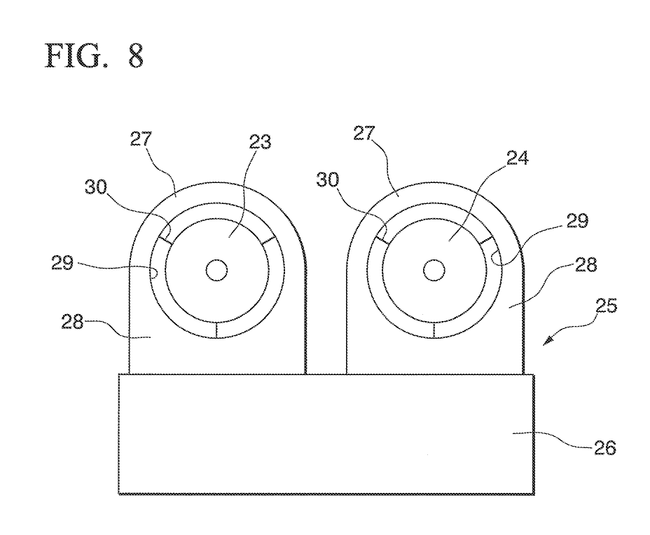

As shown in FIGS. 7 and 8, the carrier 25 includes a supporting base 26 and a plurality of substrate mounting portions 27 provided on the upper surface of the supporting base 26. It should be noted that because the present embodiment has a configuration in which two substrate mounting portions 27 are mounted, two nonmagnetic substrates 80 mounted onto these substrate mounting portions 27 will be treated as a first deposition substrate 23 and a second deposition substrate 24, respectively.

The substrate mounting portion 27 is configured such that a circular through hole 29 having a diameter slightly greater than the outer circumference of each of the deposition substrates 23 and 24 is formed in a plate body 28 with a thickness that is equal to or about several times more than the thickness of each of the first and second deposition substrates 23 and 24, and a plurality of supporting members 30 that are projected toward the inner side of the through hole 29 are provided around the through hole 29. In the substrate mounting portions 27, the first and second deposition substrates 23 and 24 are fitted into the through holes 29, and the edges thereof are engaged with the supporting members 30, thereby holding the deposition substrates 23 and 24 are held upright (with the principal surfaces of the substrates 23 and 24 being parallel to the direction of gravity). That is, the substrate mounting portions 27 are provided in parallel on the upper surface of the supporting base 26 such that the principal surfaces of the first and second deposition substrates 23 and 24 that are mounted on the carrier 25 are substantially orthogonal to the upper surface of the supporting base 26 while being substantially on the same plane.

In addition, the aforementioned processing chambers 5, 6, 8 to 13, 15, 16, and 18 to 20 include two processing devices on both sides of the carrier 25, and also a vacuum pump 36. In this case, for example, a deposition process or the like is performed on the first deposition substrate 23 arranged on the left side of the carrier 25 in a state where the carrier 25 is stopped at a first processing position shown by a solid line in FIG. 7. Thereafter, the carrier 25 moves to a second processing position shown by a dashed line in FIG. 7, and a deposition process or the like can be performed on the second deposition substrate 24 arranged on the right side of the carrier 25 in a state where the carrier 25 is stopped at the second processing position.

It should be noted that when four processing devices are provided at both sides of the carrier 25 so as to face the first and second deposition substrates 23 and 24, the movement of the carrier 25 is no longer needed, and a deposition process or the like can be performed on the first and second deposition substrates 23 and 24 held by the carrier 25 at the same time.

After the deposition process, the first and second deposition substrates 23 and 24 are detached from the carrier 25, and only the carrier 25 having a carbon film deposited thereon is transported into the ashing chamber 3A. Then, an oxygen gas is introduced into the ashing chamber 3A through an arbitrary portion of the ashing chamber, and the oxygen gas is used to generate oxygen plasma in the ashing chamber 3A. When the oxygen plasma comes into contact with the carbon film deposited on the surface of the carrier 25, the carbon film is decomposed into CO or CO₂ gas and removed.

### PREFERRED EMBODIMENTS OF THE INVENTION

Hereinafter, the effects of the present invention are made more apparent by the following examples. It should be noted that the present invention is not limited to the following examples and can be appropriately modified without departing from the spirit and scope of the present invention.

### Example

In this Example, first, an aluminum substrate plated with NiP was prepared as a nonmagnetic substrate. Then, an in-line type film forming apparatus shown above in FIG. 6 was used to sequentially laminate soft magnetic layers that were made of FeCoB and had a film thickness of 60 nm, intermediate layers that were made of Ru and had a film thickness of 10 nm, and recording magnetic layers that were made of a 70Co-5Cr-15Pt-10SiO₂ alloy and had a film thickness of 15 nm, thereby forming magnetic layers on both sides of the nonmagnetic substrate that was mounted on a carrier made of A5052 aluminum alloy.

Next, the nonmagnetic substrate mounted on the carrier was transported to a processing chamber having the same apparatus configuration as that of the film forming apparatus shown above in FIG. 1, and protective layers composed of carbon films were formed on both sides of the nonmagnetic substrate having the magnetic layers formed thereon.

More specifically, the processing chamber had a cylindrical shape with an outer diameter of 180 mm and a length of 250 mm, and the chamber wall of the processing chamber was made of SUS304. A coil-shaped cathode electrode that had a length of about 30 mm and was made of tungsten and a cylindrical anode electrode surrounding the cathode electrode were provided inside the processing chamber. The anode electrode was made of SUS304 and had an outer diameter of 140 mm and a length of 40 mm. In addition, the distance between the cathode electrode and the nonmagnetic substrate was set to 160 mm. Further, a cylindrical permanent magnet was arranged so as to surround the chamber wall. The permanent magnet had an inner diameter of 185 mm and a length of 40 mm, and was arranged such that the anode electrode was positioned at the center of the permanent magnet, the S pole was located close to the substrate, and the N pole was located close to the cathode electrode. The total magnetic force of the permanent magnet was 50 G (5 mT).

A toluene gas was used as the raw material gas. Then, the carbon film was formed with a thickness of 3.5 nm under the following deposition conditions: a gas flow rate of 2.9 SCCM; a reaction pressure of 0.3 Pa; a cathode power of 225 W (AC 22.5 V and 10 A); a voltage of 75 V between the cathode electrode and the anode electrode; a current of 1,650 mA; a pulsed, ion accelerating voltage of −400 V applied between the anode and the cathode; a pulse width of 60 milliseconds; a frequency of 13 Hz; an instantaneous current of 60 mA; and a deposition time of 10 seconds.

### Comparative Example

In this Comparative Example, a deposition process was carried out in the same manner as in the above example, although the accelerating voltage applied between the anode and the cathode was steadily applied. Note that the deposition time was set to 8 seconds to form a carbon film with a film thickness of 3.5 nm.

### (Evaluation of Magnetic Recording Media)

Then, the Raman spectroscopy, scratch test, measurement of the contact angle of the surface of the carbon film relative to pure water, and corrosion test were performed on the magnetic recording media obtained in the Example and Comparative Example.

For the Raman spectroscopy, a Raman spectrometer manufactured by JEOL was used to measure B/A values. Here, the B/A value refers to a calculated value, where B indicates the peak intensity of the Raman spectrum and A indicates the peak intensity when the base line correction is performed. As the B/A value is reduced, the amount of polymer components in the carbon film is reduced, indicating an increase in the hardness of the carbon film.

For the scratch test, an SAF tester manufactured by Kubota Corporation was used. The test conditions were as follows: a magnetic recording medium was rotated at 12,000 rpm; a PP6 head was used to repeatedly seek the surface of a disk for two hours at a speed of 5 inches/sec; and then, the presence of the scratch was confirmed with a light microscope. 20 pieces of magnetic recording media were inspected and the ratio for the number of magnetic recording media having scratches was evaluated.

For the measurement of contact angle of the surface of the carbon film relative to pure water, a droplet of pure water was added dropwise onto the surface of the carbon film, and the water droplet was observed from the side surface (a plane viewed from a direction that is parallel to the carbon film surface) to measure the angle between the surface of the carbon film and the water droplet.

For the corrosion test, the magnetic recording medium was allowed to stand for 96 hours at a temperature of 90° C. and a humidity of 90%, and then, the number of corrosion spots generated on the surface of the magnetic recording medium was counted using an optical surface inspection apparatus.

TABLE 1

| | Example | Comparative Example |
|---|---|---|
| Raman spectroscopy | 1.3 | 1.4 |
| Scratch test | 15 (%) | 20 (%) |
| Measurement of contact angle | 50 (°) | 65 (°) |
| Corrosion test | 120 (/plane) | 150 (/plane) |

From the results of the Raman spectroscopy, it became clear that in the case of using a film forming method of the present invention, a carbon film having a small B/A value was obtained. That is, it became apparent that the carbon film of the magnetic recording medium manufactured by using the present invention was a hard carbon film with a large amount of sp3 component.

In addition, from the results of the scratch test, it became clear that in the case of using a film forming method of the present invention, a hard carbon film was obtained, which was less likely to generate scratches even when the thickness of the carbon film was reduced.

From the measurements of contact angle relative to pure water, the carbon film obtained by using a film forming method of the present invention had a low contact angle relative to pure water, and thus the wettability with respect to a lubricant was also expected to be high.

From the results of the corrosion test, it became clear that in the case of using a film forming method of the present invention, the occurrence of corrosion was reduced even when the thickness of the carbon film was reduced. That is, it became apparent that the carbon film of the magnetic recording medium manufactured by using the present invention was a dense carbon film with high corrosion resistance.

### INDUSTRIAL APPLICABILITY

According to the present invention, a dense carbon film exhibiting high wettability with respect to a lubricant and having high hardness can be formed; and in the case of using this carbon film as a protective film for magnetic recording media or the like, the distance between the magnetic recording medium and the magnetic head can be narrowed down because the film thickness of the carbon film can be further reduced. As a result, it is possible to increase the recording density of the magnetic recording medium and also to enhance the corrosion resistance of the magnetic recording medium.

### REFERENCE NUMERALS

80 Nonmagnetic substrate
81 Soft magnetic layer
82 Intermediate layer
83 Magnetic recording layer
84 Protective layer
85 Lubricant film
810 Magnetic layer
101 Deposition chamber
102 Holder
103 Introduction pipe
104 Cathode electrode
105 Anode electrode
106 First power supply
107 Second power supply
108 Third pulsed power supply
109 Permanent magnet
110 Exhaust pipe

1. A method of forming a carbon film comprising:
introducing a raw material gas containing carbon and hydrogen into a deposition chamber having a reduced pressure;
ionizing the gas by electric discharge between a filamentous cathode electrode that is heated through energization and an anode electrode provided in a periphery of the cathode electrode; and
accelerating the ionized gas by a bias voltage that is applied to a substrate to irradiate a surface of the substrate with the accelerated gas, thereby forming a carbon film on the surface of the substrate,
wherein a pulsed negative voltage is employed as the bias voltage to be applied to the surface of the substrate.

2. The method of forming a carbon film according to claim 1, wherein a peak voltage of the pulsed negative voltage is within the range of −30 to −500 V.

3. The method of forming a carbon film according to claim 1, wherein a frequency of the pulsed negative voltage is within the range of 5 to 50 Hz.

4. The method of forming a carbon film according to claim 1,
wherein a pulse width of the pulsed negative voltage is within the range of 15 milliseconds to 150 milliseconds.

5. A method of manufacturing a magnetic recording medium comprising forming a carbon film on a nonmagnetic substrate with at least a magnetic layer formed therein by using the method of forming a carbon film according to claim 1.
